(19) United States
(12) Patent Application Publication
(10) Pub. No.: US 2025/0275245 A1
(43) Pub. Date: Aug. 28, 2025

(54) Display Apparatus

(71) Applicant: LG Display Co., Ltd., Seoul (KR)

(72) Inventors: Min-Jae Jeong, Goyang-si (KR); Jung-Hyun Kim, Paju-si (KR)

(21) Appl. No.: 18/909,278

(22) Filed: Oct. 8, 2024

(30) Foreign Application Priority Data
Feb. 26, 2024 (KR) 10-2024-0027520

(51) Int. Cl. H01L 27/12; G09G 3/20

(52) U.S. Cl. CPC H10D 86/60; G09G 3/2092; H10D 86/441; G09G 2300/0426; G09G 2320/0247

(57) ABSTRACT

Disclosed is a display apparatus including: a substrate including a non-display area surrounding the display area; a plurality of signal lines on the display area of the substrate; and a plurality of link wirings electrically connected to the signal lines and on a link area of the non-display area of the substrate, the plurality of link wirings include an intersection point where adjacent link wirings are arranged to intersect each other.

### CROSS-REFERENCE TO RELATED APPLICATION

This application claims priority from Republic of Korea Patent Application No. 10-2024-0027520 filed on Feb. 26, 2024, which is hereby incorporated by reference in its entirety.

### TECHNICAL FIELD

The present disclosure relates to a display device.

### BACKGROUND

Display apparatus are applied to various electronic devices such as televisions (TVs), smartphones, laptops, and tablets. To this end, research is continuing to develop a display device that is thinner, lighter, and has lower power consumption.

Examples of the display apparatus may include a liquid crystal display device (LCD), a field emission display device (FED), and organic light-emission display device (OLED).

### SUMMARY

A purpose of the solution according to the embodiment of the present disclosure is to provide a display apparatus having a dual link wiring structure in which a plurality of link wirings are disposed in different layers, such that the plurality of link wirings may be disposed in a limited bezel area.

Furthermore, a purpose according to the embodiment of the present disclosure is to provide a display apparatus in which the electric field generated between the link wirings adjacent to each other in the dual link wiring structure may be reduced to prevent unnecessary direct current voltage from being generated, thereby preventing a flicker phenomenon of the image.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means described in the present disclosure or combinations thereof.

In order to achieve the above purpose, in one embodiment a display apparatus comprises: a substrate including a display area and a non-display area that surrounds the display area; a plurality of signal lines on the display area of the substrate; and a plurality of link wirings that are electrically connected to the plurality of signal lines, the plurality of link wirings on a link area of the non-display area of the substrate, wherein the plurality of link wirings are disposed in different layers and a pair of link wirings from the plurality of link wirings that are adjacent to each other intersect each other at an intersection point in a plan view of the display apparatus.

In one embodiment, a display apparatus comprises: a substrate including a display area, a non-display area that surrounds the display area, a link area in the non-display area, and a pad area in the link area; a plurality of signal lines on the display area of the substrate; and a plurality of link wirings that are on the link area, the plurality of link wirings electrically connected to the plurality of signal lines, wherein a pair of link wirings that are adjacent to each other in the link area intersect each other at a first point that is closer to the display area than the pad area in a plan view of the display apparatus and intersect each other at a second point that is closer to the pad area than the display area in the plan view.

According to an embodiment of the present disclosure, due to the dual link wiring structure, a design of a narrow bezel area may be facilitated, such that a display apparatus having a high resolution and operating in a VRR (variable refresh rate) mode may be realized.

According to an embodiment of the present disclosure, the electric field generated between the link wirings adjacent to each other in the dual link wiring structure may be reduced to prevent unnecessary direct current voltage from being generated, thereby preventing a flicker phenomenon of the image from occurring under the bezel area. Therefore, a display apparatus that may operate at a low power level and thus has reduced power consumption may be realized.

Effects of the present disclosure are not limited to the effects mentioned above, and other effects not mentioned will be clearly understood by those skilled in the art from the description below.

In addition to the above effects, specific effects of the present disclosure are described together while describing specific details for carrying out the present disclosure.

### BRIEF DESCRIPTION OF DRAWINGS

FIG. 1 is a diagram showing a schematic configuration of a display apparatus according to embodiments of the present disclosure.

FIG. 2 is a plan view of a display panel according to some embodiments of the present disclosure.

FIG. 3 is an enlarged plan view of an area 3 in FIG. 2 according to an embodiment of the present disclosure.

FIG. 4 is an enlarged plan view of an area 4 in FIG. 2 according to an embodiment of the present disclosure.

FIG. 5 is a cross-sectional view cut along a line 5-5 in FIG. 4 according to an embodiment of the present disclosure.

FIG. 6 is a cross-sectional view showing electric field generation of a dual link wiring according to an embodiment of the present disclosure.

FIG. 7 is an enlarged plan view of an area 7 in FIG. 2 according to an embodiment of the present disclosure.

FIG. 8 is an enlarged plan view of an area 8 in FIG. 2 according to an embodiment of the present disclosure.

FIG. 9 is a cross-sectional view cut along a line 9-9 in FIG. 8 according to an embodiment of the present disclosure.

FIG. 10 is a diagram measuring flicker according to examples of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or periods, these elements, components, regions, layers and/or periods should not be limited by these terms. These terms are used to distinguish one element, component, region, layer or section from another element, component, region, layer or period. Thus, a first element, component, region, layer or section as described under could be termed a second element, component, region, layer or period, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

It will be understood that when an element or layer is referred to as being “connected to”, or “connected with” another element or layer, it may be directly on, connected to, or connected to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display apparatus according to each embodiment of the present disclosure will be described with reference to the attached drawings.

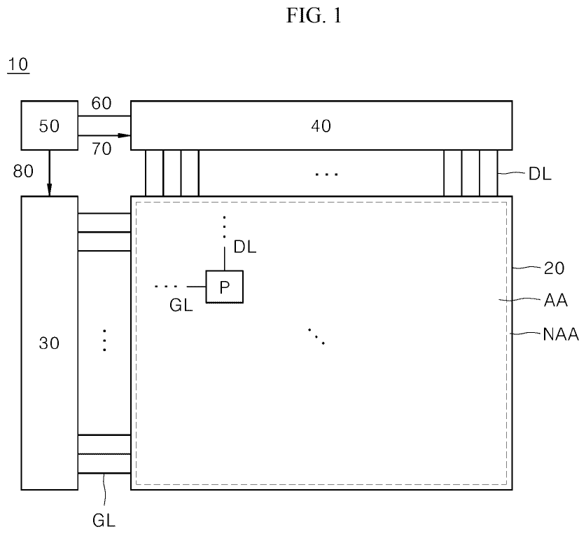

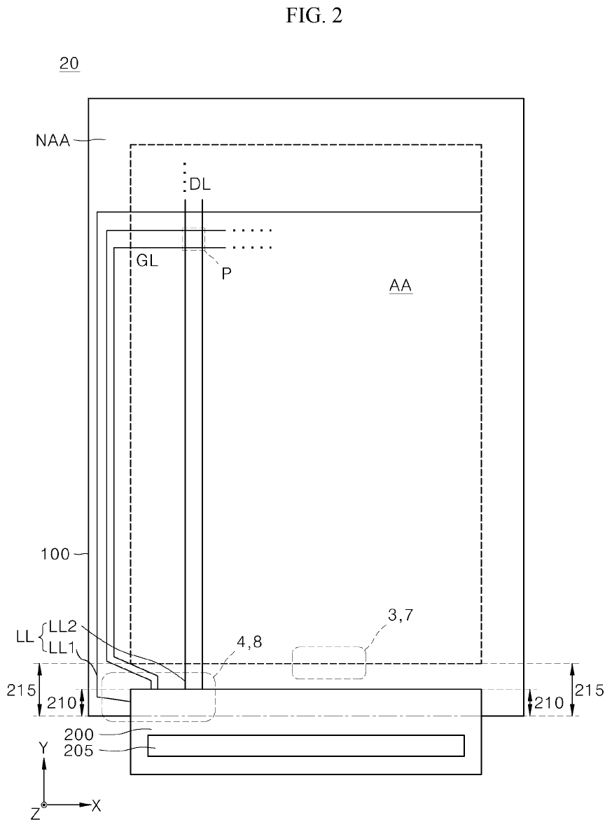

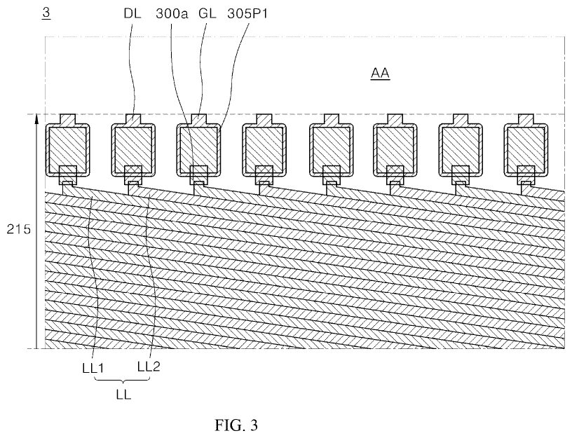

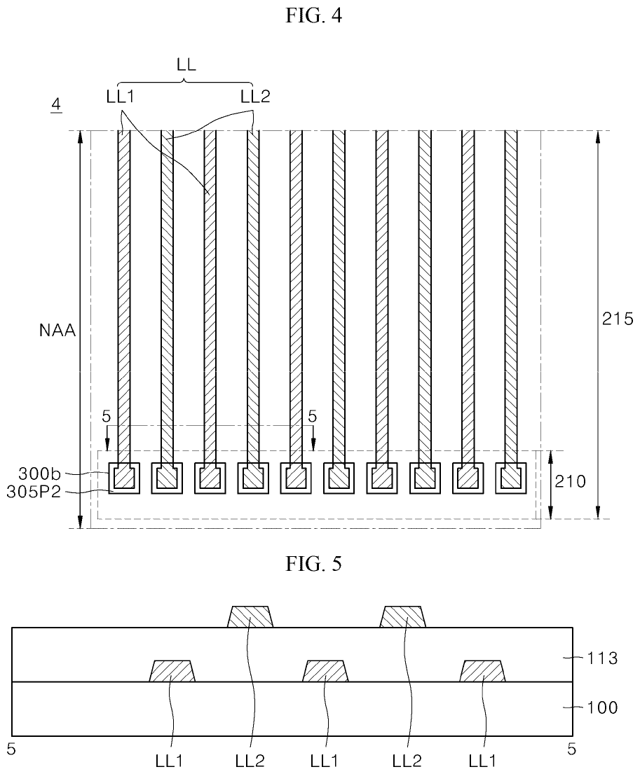

FIG. 1 is a diagram showing a schematic configuration of a display apparatus according to embodiments of the present disclosure. FIG. 2 is a plan view of a display panel according to some embodiments of the present disclosure. FIG. 3 is an enlarged plan view of an area 3 in FIG. 2 according to an embodiment of the present disclosure. FIG. 4 is an enlarged plan view of an area 4 in FIG. 2 according to an embodiment of the present disclosure.

Referring to FIG. 1 and FIG. 2, a display apparatus 10 may include a display panel 20 including a display area AA and a non-display area NAA surrounding display area AA, and panel driver 30, 40, and 50 for driving the display panel 20.

The panel driver 30, 40, and 50 may include the gate driver 30, the data driver 40, and the timing controller 50.

A plurality of signal lines GL and DL may be disposed in the display panel 20. The signal lines GL and DL may include a plurality of gate lines GL and a plurality of data lines DL. The plurality of gate lines GL may transmit a scan signal of the gate driver 30 to the display area AA, and the plurality of data lines DL may transmit a data signal of the data driver 40 to the display area AA.

The display area AA may include a plurality of pixels P respectively disposed in intersections of the plurality of gate lines GL and the plurality of data lines DL and arranged in a matrix form. The plurality of pixels P arranged in the display area AA may operate in an active matrix scheme. Each of the plurality of pixels P may include a thin-film transistor TFT disposed at each of the intersections of the plurality of data lines DL and the plurality of gate lines GL, and a pixel electrode electrically connected to the thin-film transistor TFT.

The display area AA may emit light of a wavelength region corresponding to one color among a plurality of different colors using each of the plurality of pixels P. In this regard, the plurality of colors may include red, green, and blue. Alternatively, the plurality of colors may further include white. For example, each of the plurality of pixels P operating in the active matrix scheme may include a liquid crystal cell. However, embodiments of the present disclosure are not limited thereto. In another example, each of the plurality of pixels may include an organic light-emission diode (OLED).

The timing controller 50 may control an operation timing of each of the gate driver 30 and the data driver 40.

For example, the timing controller 50 may send a data control signal 70 to control the operation timing of the data driver 40 and a gate control signal 80 to control the operation timing of the gate driver 30 based on various timing signals received from an external source.

The gate driver 30 may sequentially supply the scan signal to the plurality of gate lines GL during one frame period for image display based on the gate control signal 80 to control an operation timing of each of the plurality of pixels. The gate driver 30 may be located on only one side of the display panel 20 or on each of both opposing sides thereof.

The data driver 40 may convert the image data received from the timing controller 50 into an analog data voltage based on the data control signal 70. The data driver 40 may supply the data voltage to each data line DL in accordance with a timing at which the scan signal is applied to each pixel corresponding to each gate line GL.

The timing controller 50 may be mounted on a printed circuit board or a flexible printed circuit board and may be electrically connected to the gate driver 30 and the data driver 40.

Referring to FIGS. 1 to 4, the display panel 20 according to an embodiment of the present disclosure may include a substrate 100 including a display area AA and a non-display area NAA surrounding the display area AA.

The plurality of pixels P may be disposed on the display area AA of the substrate. A video or image may be displayed in the display area AA via the plurality of pixels P. On the non-display area NAA of the substrate, several drivers may be disposed to drive the plurality of pixels P disposed on the display area AA. For example, the drivers may include, but is not limited to, the gate driver 30, the data driver 40, and the timing controller 50.

The plurality of data lines DL and the plurality of gate lines GL may be disposed on the display area AA of the base substrate 100. The plurality of data lines DL may be arranged to intersect the plurality of gate lines GL. Each pixel P area may be defined by each data line DL and each gate line GL that intersect each other. The pixel P may be electrically connected to the gate line GL and the data line DL. The plurality of pixels P may be disposed on the display area AA of the base substrate 100 and may be arranged in a matrix scheme (M*N, where M and N are natural numbers). Accordingly, the plurality of gate lines GL and the plurality of data lines DL which are electrically connected to the pixels P may be arranged in a matrix form.

A link area 215 and a pad area 210 may be located on the non-display area NAA of the base substrate 100. The pad area 210 may be located on one edge of the non-display area NAA and may include a plurality of link pad 305P2 (see FIG. 4). For example, the pad area 210 may be disposed at a lower edge of the non-display area NAA. The link area 215 may overlap the pad area 210. The non-display area NAA may be referred to as a bezel area.

The plurality of gate lines GL extending from the display area AA to the non-display area NAA may be arranged in a corresponding manner to the plurality of electrode pad 305P1 (see FIG. 3). Each of the plurality of gate lines GL may be electrically connected to each of a plurality of link wirings LL disposed in the non-display area NAA via each first connection electrode 300a.

Each of the plurality of link wirings LL may extend toward the pad area 210 of the non-display area NAA so as to be connected to each link pad 305P2. In other words, one end of the gate line GL may be connected to an electrode pad 305P1 via the first connection electrode 300a, and the other end thereof may be connected to the link pad 305P2 via a second connection electrode 300b. In the present disclosure, the gate line GL is described by way of example. The principle applied to the gate line may be equally applied to the data line DL. For example, one end of the data line DL may be connected to the electrode pad 305P1, and the other end thereof may be connected to the link pad 305P2.

The plurality of link pads 305P2 (see FIG. 4) arranged in the pad area 210 may be attached to a flexible circuit board 200 including an integrated circuit 205 and electrically connected to a printed circuit board. The printed circuit board may include an integrated circuit chip and may provide various powers and various signals to the display area AA to drive the pixels P arranged on the display area AA. For example, the various signals may include high-potential voltage, low-potential voltage, a scan signal, and a data signal. The flexible circuit board 200 may be embodied as a chip-on-film (COF) including a circuit film on which an integrated circuit chip IC is mounted. However, embodiments of the present disclosure are not limited thereto. For example, the integrated circuit chip IC may be mounted on a TCP (Tape Carrier Package) and bonded to an edge of the display panel 20 in a TAB (Tape Automated Bonding) process.

In order to provide a user with the widest possible display area AA in a limited size of the display device, an area size of the non-display area NAA, that is, the bezel area, is decreasing. A display apparatus having a high resolution and operating in a VRR (Variable Refresh Rate) mode is required.

The display apparatus having the high resolution and operating in the VRR (Variable Refresh Rate) mode requires a larger number of signal lines. Accordingly, the number of signal lines and the number of the link wirings corresponding thereto are also increasing. However, as the number of the link wirings increases, various problems are occurring. For example, while the number of the link wirings increases, the bezel area decreases, making it difficult to place the plurality of link wiring in the same layer.

Accordingly, in order to place the plurality of link wirings in a narrow bezel area, the display apparatus according to an embodiment of the present disclosure may include a dual link wiring structure.

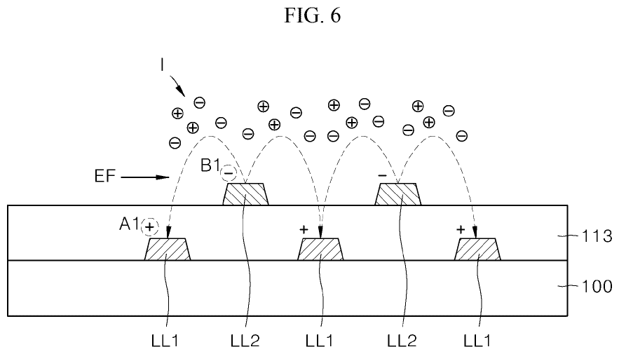

FIG. 5 is a cross-sectional view cut along a line 5-5 in FIG. 4 according to an embodiment of the present disclosure. FIG. 6 is a cross-sectional view showing electric field generation of a dual link wiring according to an embodiment of the present disclosure.

Referring to FIGS. 3 to 5, the dual link wiring structure may be a structure in which neighboring link wiring LL1 and LL2 are formed in different layers, respectively. In one embodiment, a first link wiring LL1 neighbors a second link wiring LL2 without an intermediate link wiring LL between the first link wiring LL1 and the second link wiring LL2 in a plan view of the display device. The adjacent link wirings LL1 and LL2 may include an odd-numbered first link wiring LL1 and an even-numbered second link wiring LL2.

For example, the odd-numbered first link wiring LL1 may be disposed in a first layer, and the even-numbered second link wiring LL2 adjacent to the odd-numbered first link wiring LL1 may be disposed in a second layer which is a different layer from the first layer. In one embodiment, the first layer is closer to the substrate than the second layer.

Referring to FIG. 3 and FIG. 4, in a first area adjacent to the display area AA of the link area 215, the odd-numbered first link wiring LL1 may be electrically connected to the gate line GL, and the even-numbered second link wiring LL2 may be electrically connected to the data line DL. However, embodiments of the present disclosure are not limited thereto. The odd-numbered first link wiring LL1 and the even-numbered second link wiring LL2 arranged in the first area may extend to the pad area 210 of the link area 215.

The dual link wiring structure may reduce a width between the adjacent first and second link wirings LL1 and LL2. Accordingly, a narrow bezel or a zero bezel may be realized by reducing an area occupied with the first and second link wirings LL1 and LL2 in the bezel area.

The odd-numbered first link wiring LL1 may be located in the first layer and on the base substrate 100 and may be made of the same material as a material of a gate electrode GE and may be formed in the same process as a process in which the gate electrode GE is formed. The even-numbered second link wiring LL2 may be located in the second layer different from the first layer, and may be made of the same material as a material of a source/drain electrode SD and may be formed in the same process as a process in which the source/drain electrode SD is formed. A gate insulating layer 113 may be disposed between the odd-numbered first link wiring LL1 and the even-numbered second link wiring LL2.

Referring to FIG. 6, according to an embodiment of the present disclosure, a signal A1 of a first polarity may be transmitted to the odd-numbered first link wiring LL1, and a signal B1 of a second polarity may be transmitted to the even-numbered second link wiring LL2. The first polarity and the second polarity may be opposite to each other. For example, the first polarity may be a positive polarity (+), and the second polarity may be a negative polarity (−). Thus, the signal of the first polarity may be a positive polarity signal and the signal of the second polarity may be a negative polarity signal. In one example, the signal of the first polarity may be a positive polarity (+) data voltage, and the signal of the second polarity may be a negative polarity (−) data voltage. Alternatively, the second polarity may be a positive polarity (+), and the first polarity may be a negative polarity (−). In this case, the signal of the second polarity may be a positive polarity (+) data voltage, and the signal of the first polarity may be a negative polarity (−) data voltage.

A horizontal electric field EF may be generated between the odd-numbered first link wiring LL1 to which the signal A1 of the first polarity is transmitted and the even-numbered second link wiring LL2 which is adjacent to the odd-numbered first link wiring LL1 and to which the signal B1 of the second polarity opposite to the first polarity is transmitted. The electric field EF may increase as a distance between the first and second link wirings LL1 and LL2 becomes smaller.

When the electric field is generated, ionic components I may be trapped between the first and second link wirings LL1 and LL2. As the electric field is generated between each of the plurality of odd-numbered first link wirings LL1 and each of the plurality of even-numbered second link wiring LL2 adjacent to each other, an amount of the ionic components I trapped therebetween may increase.

The increase in the amount of the trapped ionic components I may cause a residual direct current voltage DC. The remaining direct current voltage DC may cause a variation in a common voltage Vcom which should be applied, at a constant level, to each pixel. When there is the variation in the common voltage Vcom, an amount of the voltage charged to each pixel may vary from frame to frame. As a result, a flicker phenomenon may occur in which a defect in which the image or video emitted from the display area AA flickers is visible to the user.

The flicker phenomenon may reduce the user's sense of immersion in the image or video to reduce the reliability of the display apparatus.

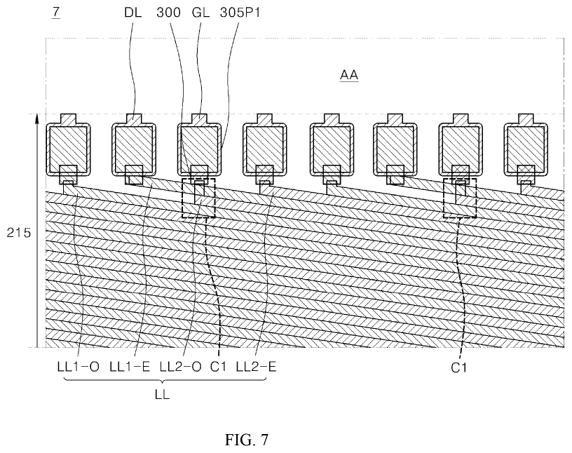

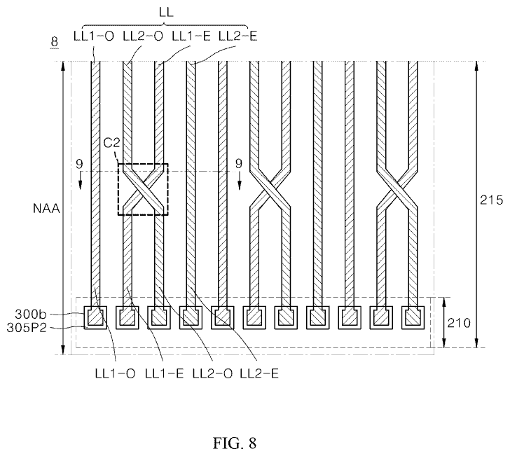

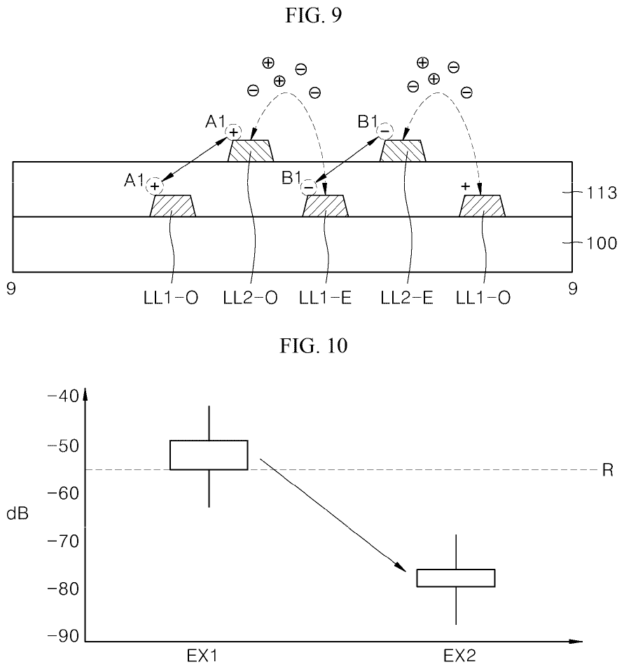

FIG. 7 is an enlarged plan view of an area 7 in FIG. 2. FIG. 8 is an enlarged plan view of an area 8 in FIG. 2 according to an embodiment of the present disclosure. FIG. 9 is a cross-sectional view cut along a line 9-9 in FIG. 8 according to an embodiment of the present disclosure. FIG. 10 is a diagram measuring a flicker level according to embodiments of the present disclosure. In this regard, FIG. 9 shows the electric field generation of the dual link wiring according to another embodiment of the present disclosure.

Referring to FIGS. 7 to 9, the dual link wiring structure may be a structure in which neighboring link wirings LL are respectively formed in different layers. The link wirings LL may include the first link wiring LL1 and the second link wiring LL2. For example, the first link wiring LL1 may be disposed in the first layer, and the second link wiring LL2 may be disposed in the second layer that is different from the first layer. In one example, an odd-numbered first link wiring LL1-O may be disposed in the first layer, and an odd-numbered second link wiring LL2-O adjacent to the odd-numbered first link wiring LL1-O may be disposed in the second layer.

First and second areas of the link area 215 may respectively include a plurality of intersection points C1 and C2 at which the first link wiring LL1 and the second link wiring LL2 (e.g., a pair of link wirings) intersect each other in a plan view of the display device. Portions of the first link wiring LL1 and the second link wiring LL2 are spaced apart from each other at locations other than the intersection points C1 and C2 in the plan view. In one embodiment, the first area may be adjacent to the display area AA, and the second area may be adjacent to the pad area 210. The first area may be one side edge of the link area 215, and the second area may be the other side edge opposite to one side edge of the link area 215.

Referring to FIG. 7, in the first area adjacent to the display area AA of the link area 215, the odd-numbered second link wiring LL2-O may be electrically connected to the gate line GL, and the even-numbered first link wiring LL1-E may be electrically connected to the data line DL. However, embodiments of the present disclosure are not limited thereto.

The first area of the link area 215 may include the first intersection point C1 at which the even-numbered first link wiring LL1-E and the odd-numbered second link wiring LL2-O intersects each other. As shown in FIG. 8, the even-numbered first link wiring LL1-E and the odd-numbered second link wiring LL2-O that intersect each other at the first intersection point C1 of the first area of the link area 215 may extend toward the second area of the link area 215.

The plurality of first link wirings LL1-O and LL1-E may be located in the first layer on the base substrate 100 and may be made of the same material as that of the gate electrode GE and may be formed in the same process as a process in which the gate electrode is formed.

The plurality of second link wirings LL2-O and LL2-E may be located in the second layer different from the first layer, and may be made of the same material as that of the source/drain electrode SD and may be formed in the same process as a process in which the source/drain electrode SD is formed.

The gate insulating layer 113 may be disposed between the plurality of first link wirings LL1-O and LL1-E and the plurality of second link wirings LL2-O and LL2-E. However, embodiments of the present disclosure are not limited thereto. For example, a plurality of insulating layers may be disposed between the plurality of first link wirings LL1-O and LL1-E and the plurality of second link wirings LL2-O and LL2-E.

Referring to FIG. 7 and FIG. 8, the even-numbered first link wiring LL1-E and the odd-numbered second link wiring LL2-O that intersect each other at the first intersection point C1 of the first area of the link area 215 may extend toward the second area of the link area 215.

As the even-numbered first link wiring LL1-E and the odd-numbered second link wiring LL2-O intersect each other at the first intersection point C1, the odd-numbered second link wiring LL2-O may be disposed adjacent to the odd-numbered first link wiring LL1-O. For example, the odd-numbered second link wiring LL2-O may be disposed between the odd-numbered first link wiring LL1-O and the even-numbered first link wiring LL1-E. The even-numbered first link wiring LL1-E may be disposed between the odd-numbered second link wiring LL2-O and the even-numbered second link wiring LL2-E.

The even-numbered first link wiring LL1-E and the odd-numbered second link wiring LL2-O that intersect each other at the first intersection point C1 of the first area of the link area 215 may intersect with each other again at the second intersection point C2 of the second area of the link area 215.

The even-numbered first link wiring LL1-E and the odd-numbered second link wiring LL2-O that intersect each other at the second intersection point C2 may extend to the pad area 210 and may be electrically connected to the link pad 305P2 via the second connection electrode 300b.

As the even-numbered first link wiring LL1-E and the odd-numbered second link wiring LL2-O intersect each other at the second intersection point C2, the even-numbered first link wiring LL1-E may be disposed adjacent to the odd-numbered first link wiring LL1-O in the pad area 210. Furthermore, the even-numbered second link wiring LL2-E may be disposed adjacent to the odd-numbered second link wiring LL2-O.

Accordingly, one link wiring group LL may be comprised of the odd-numbered first link wiring LL1-O, the even-numbered first link wiring LL1-E, the odd-numbered second link wiring LL2-O, and the even-numbered second link wiring LL2-E arranged along the first direction in the pad area 210.

For example, the first direction may be a X-axis direction of the base substrate 100 (see FIG. 2). In one example, the first direction may be a horizontal direction. A plurality of link wiring groups LL may be arranged on the base substrate 100.

The odd-numbered second link wiring LL2-O may be disposed adjacent to the odd-numbered first link wiring LL1-O. For example, the odd-numbered second link wiring LL2-O may be disposed between the odd-numbered first link wiring LL1-O and the even-numbered first link wiring LL1-E. The even-numbered first link wiring LL1-E may be disposed between the odd-numbered second link wiring LL2-O and the even-numbered second link wiring LL2-E.

Referring to FIG. 8 and FIG. 9, according to another embodiment of the present disclosure, the signal A1 of the first polarity may be transmitted to the odd-numbered first link wiring LL1-O disposed in the first layer in the link area 215 of the non-display area NAA.

The signal A1 of the same first polarity as that of the signal transmitted to the odd-numbered first link wiring LL1-O may also be transmitted to the odd-numbered second link wiring LL2-O which is adjacent to the odd-numbered first link wiring LL1-O and disposed in the second layer. The first layer and the second layer may be different layers. In one example, the second layer may be present on top of the first layer. For example, the first polarity may be a signal of the positive polarity. In one example, the polarity signal of the positive polarity may be a positive data voltage.

The signal B1 of the second polarity may be transmitted to the even-numbered first link wiring LL1-E disposed in the first layer. The signal B1 of the same second polarity as that of the signal transmitted to the even-numbered first link wiring LL1-E may be transmitted to the even-numbered second link wiring LL2-E located in the second layer and adjacent to the even-numbered first link wiring LL1-E. For example, the second polarity may be the negative polarity. In one example, the signal of the negative polarity may be a negative data voltage.

As the signal A1 of the same first polarity is transmitted to the odd-numbered first link wiring LL1-O disposed in the first layer and the odd-numbered second link wiring LL2-O disposed in the second layer, the electric field is not generated therebetween. Furthermore, as the signal B1 of the same second polarity is transmitted to the even-numbered first link wiring LL1-E disposed in the first layer and the even-numbered second link wiring LL2-E disposed in the second layer, an electric field is not generated therebetween.

As the signal A1 of the first polarity and the signal B1 of the second polarity opposite to each other are applied to the even-numbered first link wiring LL1-E disposed in the first layer and the odd-numbered second link wiring LL2-O adjacent to the even-numbered link wiring LL1-E and disposed in the second layer which intersect each other at the plurality of intersection points C1 and C2, an electric field may be generated therebetween.

Thus, as the electric field is generated therebetween, the ionic components I may be trapped between the even-numbered first link wiring LL1-E and the odd-numbered second link wiring LL2-O. However, the amount of the trapped ionic components I may be reduced compared to the earlier embodiment described herein.

As the amount of the trapped ion components I decreases, the residual direct current voltage DC may be prevented from occurring. Accordingly, the common voltage Vcom applied to each pixel may be kept constant. As a result, the amount of the voltage charged to each pixel may be kept constant, thereby preventing or reducing the flicker phenomenon.

The flicker phenomenon cannot be recognized by the user at high refresh rates such as 120 Hz or 60 Hz. However, as the display apparatus operating in the variable refresh rate (VRR) mode operates at various refresh rates (for example, 40 Hz to 120 Hz), the flicker phenomenon should not be visible to the user even at the low refresh rates below 40 Hz.

To measure whether the flicker occurs, a flicker level value may be measured at a refresh rate as low as 24 Hz. In measuring the flicker level value at a refresh rate of 24 Hz, a flicker level value at a refresh rate of 12 Hz is also measured. Accordingly, it may be identified whether the flicker level at the refresh rate of 24 Hz is within a normal range, based on the measured flicker level value at the refresh rate of 12 Hz. For example, a reference value R at which the flicker level value is determined to be normal may be −55 dB. When the flicker level value is greater than −55 dB, this may be determined as the flicker defect.

The flicker level value measured at a refresh rate of 12 Hz may be smaller than the flicker level value measured at a refresh rate of 24 Hz. For example, when the flicker level value measured at a refresh rate of 24 Hz is −55 dB, the flicker level value measured at a refresh rate of 12 Hz may be −80 dB, which is smaller than −55 dB.

Accordingly, when the flicker level value measured at a refresh rate of 12 Hz is, for example, −80 dB or a smaller value, it may be determined that the flicker level value measured at a refresh rate of 24 Hz is within the normal range. Additionally, if the flicker level value measured at a refresh rate of 12 Hz is, for example, −55 dB or a greater value, it may be determined that the flicker level value measured at a refresh rate of 24 Hz as the flicker defect.

Referring to FIG. 11, in Comparative Example EX1, the flicker level value measured at a refresh rate of 12 Hz is greater than −55 dB. Accordingly, it may be determined that the flicker level value measured at a refresh rate of 24 Hz has a value greater than −55 dB, which is the reference value R for determining that the flicker level to be normal. Accordingly, it may be determined that Comparative Example EX1 has a flicker defect. In this regard, Comparative Example EX1 has a configuration in which the first link wiring LL1 and the second link wiring LL2 did not intersect with each other in the link area 215.

In contrast to Comparative Example, a flicker level value measured at a refresh rate of 12 Hz is smaller than −55 dB in Present Example EX2. For example, the flicker level value may have a value smaller than −80 dB. Accordingly, it may be determined that the flicker level value measured at a refresh rate of 24 Hz has a value smaller than −55 dB, which is the reference value R for determining that the flicker level to be normal. Accordingly, it may be determined that the flicker defect does not occur in Present Example EX2. In this regard, Present Example EX2 has the configuration according to another embodiment of the present disclosure that the first link wiring LL1 and the second link wiring LL2 intersect each other at the plurality of intersection points C1 and C2 in the first area and the second area of the link area 215.

Accordingly, according to another embodiment of the present disclosure, the flicker level value at a 12 Hz refresh rate is a value smaller than −80 dB. Thus, the flicker defect may be prevented or reduced. For example, the link area 215 may include the intersection points in at least the first area and the second area thereof at which the first link wiring and the second link wiring intersect each other.

Thus, preventing or reducing the occurrence of the flicker allow for increasing the user's sense of immersion in the image or video. Thus, the reliability of the display apparatus may be improved. Furthermore, the electric field generated between adjacently arranged link wirings may be prevented from increasing.

Accordingly, unnecessary direct current voltage may be prevented from being generated, thereby enabling an operation of the display apparatus at low power, thereby reducing power consumption thereof.

A display apparatus according to various aspects and embodiments of the present disclosure may be described as follows.

One aspect of the present disclosure provides a display apparatus comprising: a substrate including a non-display area surrounding the display area; a plurality of signal lines disposed on the display area of the substrate; and a plurality of link wirings electrically connected to the signal lines, respectively, and disposed on a link area of the non-display area of the substrate, wherein the plurality of link wirings include an intersection point where adjacent link wirings are arranged to intersect each other.

In accordance with some embodiments of the display apparatus, the intersection point includes: a first intersection point disposed in a first area adjacent to one end of the link area; and a second intersection point disposed in a second area adjacent to the other end opposite to the one end of the link area.

In accordance with some embodiments of the display apparatus, the first area is adjacent to the display area, and the second area is adjacent to a pad area of the non-display area.

In accordance with some embodiments of the display apparatus, the plurality of signal lines includes data lines or gate lines.

In accordance with some embodiments of the display apparatus, the link wirings include: a first link wiring disposed in a first layer on the substrate; and a second link wiring disposed in a second layer different from the first layer.

In accordance with some embodiments of the display apparatus, the first link wiring and the second link wiring intersect each other at at least one intersection point in the link area.

In accordance with some embodiments of the display apparatus, the link wirings include one link wiring group composed of: an odd-numbered first link wiring and an even-numbered first link wiring disposed in a first layer on the substrate; and an odd-numbered second link wiring and an even-numbered second link wiring disposed in a second layer different from the first layer.

In accordance with some embodiments of the display apparatus, the even-numbered first link wiring and the odd-numbered second link wiring intersect each other at a first intersection point in a first area of the link area, and intersect each other at a second intersection point in a second area of the link area, wherein the first and second areas are spaced apart from each other.

In accordance with some embodiments of the display apparatus, in the link wiring group, the odd-numbered first link wiring, the odd-numbered second link wiring, the even-numbered first link wiring, and the even-numbered second link wiring are arranged in this order in one direction and are spaced apart from each other in an area between the first intersection point and the second intersection point.

In accordance with some embodiments of the display apparatus, in the link wiring group, the odd-numbered first link wiring, the even-numbered first link wiring, the odd-numbered second link wiring, and the even-numbered second link wiring are arranged in this order in one direction and are spaced apart from each other in an area between the second intersection point and a pad area of the non-display area.

In accordance with some embodiments of the display apparatus, a signal of a first polarity is transmitted to the odd-numbered first link wiring disposed in the first layer and the odd-numbered second link wiring adjacent to the odd-numbered first link wiring and disposed in the second layer, wherein a signal of a second polarity is transmitted to the even-numbered first link wiring disposed in the first layer and the even-numbered second link wiring adjacent to the even-numbered first link wiring and disposed in the second layer, wherein the first polarity and the second polarity are opposite to each other.

In accordance with some embodiments of the display apparatus, the signal of the first polarity includes a positive data voltage, and the signal of the second polarity includes a negative data voltage.

In accordance with some embodiments of the display apparatus, the first link wiring includes the same material as a material of a gate electrode on the display area and is formed in the same process as a process in which the gate electrode is formed, wherein the second link wiring includes the same material as a material of a source/drain electrode disposed on the display area, and is formed in the same process as a process in which the source/drain electrode is formed, wherein an insulating layer is disposed between the first link wiring and the second link wiring.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A display apparatus comprising:
a substrate including a display area and a non-display area that surrounds the display area;
a plurality of signal lines on the display area of the substrate; and
a plurality of link wirings that are electrically connected to the plurality of signal lines, the plurality of link wirings on a link area of the non-display area of the substrate,
wherein the plurality of link wirings are disposed in different layers and a pair of link wirings from the plurality of link wirings that are adjacent to each other intersect each other at an intersection point in a plan view of the display apparatus.

2. The display apparatus of claim 1, wherein the intersection point includes:
a first intersection point in a first area that is closer to a first end of the link area than a second end of the link area that is opposite the first end of the link area; and
a second intersection point in a second area that is closer to the second end of the link area than the first end of the link area.

3. The display apparatus of claim 2, wherein the first area is adjacent to the display area and the second area is adjacent to a pad area of the non-display area.

4. The display apparatus of claim 1, wherein the plurality of signal lines includes at least one of data lines and gate lines.

5. The display apparatus of claim 1, wherein the plurality of link wirings include:
a first link wiring in a first layer on the substrate; and
a second link wiring in a second layer that is different from the first layer on the substrate.

6. The display apparatus of claim 5, wherein the first link wiring and the second link wiring intersect each other at one or more intersection points in the link area.

7. The display apparatus of claim 1, wherein the plurality of link wirings include at least one link wiring group, each link wiring group comprising:
an odd-numbered first link wiring and an even-numbered first link wiring in a first layer on the substrate; and
an odd-numbered second link wiring and an even-numbered second link wiring disposed in a second layer that is different from the first layer on the substrate.

8. The display apparatus of claim 7, wherein the even-numbered first link wiring and the odd-numbered second link wiring intersect each other at a first intersection point in a first area of the link area and extend toward a second area of the link area and intersect each other at a second intersection point in the second area of the link area,
wherein the first area and the second area are spaced apart from each other.

9. The display apparatus of claim 8, wherein in the at least one link wiring group, the odd-numbered first link wiring, the odd-numbered second link wiring, the even-numbered first link wiring, and the even-numbered second link wiring are sequentially arranged in one direction and are spaced apart from each other in an area between the first intersection point and the second intersection point.

10. The display apparatus of claim 8, wherein in the at least one link wiring group, the odd-numbered first link wiring, the even-numbered first link wiring, the odd-numbered second link wiring, and the even-numbered second link wiring are sequentially arranged in one direction and are spaced apart from each other in an area between the second intersection point and a pad area of the non-display area.

11. The display apparatus of claim 8, wherein the odd-numbered first link wiring in the first layer and the odd-numbered second link wiring that is adjacent to the odd-numbered first link wiring and in the second layer receive a signal of a first polarity,
wherein the even-numbered first link wiring disposed in the first layer and the even-numbered second link wiring that is adjacent to the even-numbered first link wiring and in the second layer receive a signal of a second polarity that is opposite the first polarity.

12. The display apparatus of claim 11, wherein the signal of the first polarity includes a positive data voltage, and the signal of the second polarity includes a negative data voltage.

13. The display apparatus of claim 5, wherein a material of the first link wiring is a same as a material of a gate electrode that is on the display area and the first link wiring is on a same layer as the gate electrode,
wherein a material of the second link wiring is a same as a material of a source electrode or a drain electrode that are on the display area, and the second link wiring is on a same layer as the source electrode or the drain electrode,
wherein the display apparatus further comprises an insulating layer between the first link wiring and the second link wiring.

14. A display apparatus comprising:
a substrate including a display area, a non-display area that surrounds the display area, a link area in the non-display area, and a pad area in the link area;
a plurality of signal lines on the display area of the substrate; and
a plurality of link wirings that are on the link area, the plurality of link wirings electrically connected to the plurality of signal lines,
wherein a pair of link wirings that are adjacent to each other in the link area intersect each other at a first point that is closer to the display area than the pad area in a plan view of the display apparatus and intersect each other at a second point that is closer to the pad area than the display area in the plan view.

15. The display apparatus of claim 14, wherein the pair of link wirings include a first link wiring on a first layer and a second link wiring on a second layer that is different from the first layer.

16. The display apparatus of claim 15, wherein the first link wiring receives a signal of a first polarity and the second link wiring receives a signal of a second polarity that is different from the first polarity.

17. The display apparatus of claim 16, wherein the signal of the first polarity includes a positive voltage and the signal of the second polarity includes a negative voltage.

18. The display apparatus of claim 15, wherein a material of the first link wiring is a same as a material of a gate electrode that is on the display area and the first link wiring is on a same layer as the gate electrode,
wherein a material of the second link wiring is a same as a material of a source electrode or a drain electrode that are on the display area, and the second link wiring is on a same layer as the source electrode or the drain electrode.

19. The display apparatus of claim 16, wherein a portion of the first link wiring and a portion of the second link wiring are spaced apart from each other in the plan view.

20. The display apparatus of claim 14, wherein the plurality of signal lines includes at least one of data lines and gate lines.
